(19) United States
(12) Patent Application Publication
(10) Pub. No.: US 2004/0250776 A1
(43) Pub. Date: Dec. 16, 2004

(54) Sample-setting moving stage, manufacturing apparatus for circuit pattern, and inspection apparatus for circuit pattern

(76) Inventors: Masaki Mizuochi, Hitachinaka (JP); Yoshimasa Fukushima, Hitachinaka (JP); Tadayuki Kubo, Ushiku (JP)

Correspondence Address: MCDERMOTT WILL & EMERY LLP, 600 13TH STREET, N.W., WASHINGTON, DC, 20005-3096, US

(21) Appl. No.: 10/809,795

(22) Filed: Mar. 26, 2004

(30) Foreign Application Priority Data
Mar. 26, 2003 (JP) 2003-084337

(51) Int. Cl. C23C 16/00

(52) U.S. Cl. 118/728

(57) ABSTRACT

To realize the temperature control of the sample-setting portion and enable to perform exposure or inspection of samples accurately while preventing the generation of dust, deterioration of the degree of vacuum and contamination in a vacuum atmosphere.

(Means of Solving the Problems)

The top table 21 or sample holding mechanism 7 is equipped with a temperature sensor 23, the flow path 251 of the heat-exchanging medium 241 is provided inside the non-moving fixed side guide member 181, and the temperature of the sample-setting portion is controlled through the control of the medium 241. Since the flow path 251 of the heat-exchanging medium 241 is located in a stationary portion, it is possible to control the temperature of the sample-setting portion while preventing the generation of dust due to flexible piping, damage to vacuum pump and contamination in a vacuum atmosphere caused by the heat-exchanging medium 241.

### BACKGROUND OF THE INVENTION

1. Field of the Invention

The present invention relates to a sample-setting moving stage easy to adjust the temperature, manufacturing apparatus for circuit pattern, and inspection apparatus for circuit pattern.

2. Prior Art

2. [Cited Patent Document 1]

Japanese Application Patent Laid-open Publication No. 2000-260983

[Cited Patent Document 1]

Japanese Application Patent Laid-open Publication No. Sho 62-63218

[Cited Patent Document 3]

Japanese Application Patent Laid-open publication No. Sho 63-120050

On an apparatus for manufacturing or inspecting a wafer, mask (also called “reticle”), or the like on which a circuit pattern is formed, it is a general practice that charged particle ray or extreme ultraviolet (EUV) is radiated on samples. In this practice, it is essential that the charged particle ray, or electron beam in particular, is employed under vacuum. Besides, as the light source of a projection lithography exposure system, called stepper or scanner, use of X-ray with shorter wavelength than excimer laser, or the extreme ultraviolet, is under consideration as finer and finer circuit patterns are needed. For this extreme ultraviolet, use under vacuum or reduced pressure is also essential.

Further explanation on the prior art is given below, using an electron-beam drawing apparatus that draws a circuit pattern on a sample with electron beam as an example of the manufacturing apparatus for circuit pattern.

Electron-beam drawing apparatus is a piece of equipment for forming an LSI circuit pattern on a semiconductor substrate or on a glass substrate, called mask used on an exposing apparatus such as stepper, by generating electron beams and scanning under ultra-vacuum environment. As finer and finer circuit pattern is needed, the position accuracy of the required patterns becomes severer year by year. The possible cause of an error in the position accuracy includes expansion and contraction of the sample and sample-setting table due to temperature change. Below are four major causes of the temperature change:

(1) Exposure heat on the sample caused by the electron beam (excimer laser or EUV in the case of stepper or scanner)

(2) Heat caused by ball screw or by a drive, typically friction drive

(3) Heat caused by sliding of a drive mechanism, typically a cross roller guide

(4) Change of the ambient temperature

The expansion or contraction of the sample leads directly to the error in the pattern, and the expansion or contraction of the sample-setting table causes the change in the distance between the mirror and sample, resulting in deteriorated position accuracy of the pattern.

In order to solve the above problems, a construction as follows is proposed in the Japanese Application Patent Laid-open Publication No. 2000-260683. That is, the construction is provided with a heat sink for cooling the sliding portion, which transfers the drive force to the stage by means of friction, and the driving source, and also with a heater for adjusting a sample and sample holding means to a desired temperature with the aid of the temperature sensor installed in the holding means. To be concrete, in order to eliminate the heat from the ultrasonic motor itself and heat generation at a sliding portion that generates the driving force, a heat sink 10 is placed inside the moving intermediate block 8 that constitutes the guide.

For reference sake, a technique of the gas lubrication, using air, for the movement of the sample-setting table has been disclosed in the Japanese Application Patent Laid-open Publication Nos. Sho 62-63218 63218 and Sho 63-120050.

### SUMMARY OF THE INVENTION

In order to install a heat sink throughout the moving portion, however, it is necessary to let coolant flow through in flexible piping, typically tube or bellows. If resin tube or metallic bellows is employed, there arises a problem of dust generation caused by friction involved in the stage movement or fatigue caused by repeated movement. If the tube or bellows fatigues under vacuum and consequently crack or chip is caused, the coolant flushes out in the vacuum. Where ordinary coolant, typically water, is employed, there is a risk that the coolant evaporates and consequently the degree of vacuum degrades instantly, which in turn may damage the vacuum pump. In addition, since the evaporated coolant spreads everywhere in the vacuum, the inside wall of the vacuum is contaminated. When this accident is caused, the manufacturing apparatus ceases to operate, maintenance activities such as replacement of the broken pipes, check of the vacuum pump, and cleaning of the inside wall of the vacuum are needed, and therefore, the time needed for staring up the apparatus is enormous. If the apparatus is used in a semiconductor manufacturing line, it becomes necessary to change the manufacturing processes.

An object of the present invention is to offer a sample-setting moving stage that, while preventing the risk of contamination in a vacuum atmosphere, realizes temperature control of the sample-setting portion and makes available the exposure and inspection with high accuracy.

Another object of the present invention is to offer a manufacturing apparatus for circuit pattern or inspection apparatus for circuit pattern equipped with a sample-setting moving stage that makes available the exposure and inspection with high accuracy.

The present invention is a sample-setting moving stage, comprising a table on which a sample is set under vacuum or reduced pressure atmosphere, a guide, consisting of a moving side and a fixed side, that guides the movement of the table by means of the relative movement of the two sides, a temperature sensor installed near the sample-setting portion, a flow path of the heat-exchanging medium that cools the sample-setting portion via the guide, and a temperature adjustment means that adjusts the temperature of the sample-setting portion by means of the heat-exchanging control; the flow path of the heat-exchanging medium being provided through the inside of the non-moving fixed side guide member of the two constituent members of the guide or through the inside of a member attached closely to the non-moving fixed side guide member.

With the above construction, the flow path of the heat-exchanging medium is located at non-moving portion, and so the temperature control of the sample-setting portion becomes possible while preventing the risk of dust generation by flexible piping, damage to the vacuum pump, and contamination of the vacuum ambient by the heat-exchanging medium.

The present invention also includes, in addition to the first and the second guides that guide the table in the X-axis and Y-axis directions in a plane, respectively, a gas-lubrication type third guide that guides the table in every direction in the plane, and the flow path of the heat-exchanging medium is provided through the inside of the non-moving fixed side guide member of the two constituent members of the third guide or through the inside of a member attached to the fixed side guide member.

In connection with the above, it is preferable that the flow path of the heat-exchanging medium is so widely extended that the flow path is located just under the table almost everywhere in the plane of the table movement.

With the above construction, because the flow path of the heat-exchanging medium is located at non-moving portion which is closer to the sample-setting portion in terms of both distance and heat transfer, the temperature control of the sample-setting portion can be performed more effectively.

Other objects and constructions of the present invention will be explained in the course of describing the preferred embodiments hereunder.

### BRIEF DESCRIPTION OF THE DRAWINGS

FIG. 1 is brief construction diagram of an electron-beam drawing apparatus that employs the sample-setting moving stage according to an embodiment of the invention.

FIG. 2 is plan view of the stage 4 shown in FIG. 1 according to an embodiment of the invention.

FIG. 3 is side view of the stage 4 shown in FIG. 1 according to the first embodiment of the invention.

FIG. 4 is side view of the stage shown in FIG. 1 according to the second embodiment of the invention.

FIG. 5 is plan view of the stage 4 shown in FIG. 1 according to the third embodiment of the invention.

FIG. 6 is cross section A-A of FIG. 5.

FIG. 7 is cross section B-B of FIG. 5.

FIG. 8 is explanatory figure of a gas-lubrication type guide according to the third embodiment of the invention.

FIG. 9 is side view of the stage 4, partly shown in cross section, according to the fourth embodiment of the invention.

FIG. 10 is side view of the stage 4, partly shown in another cross section, according to the fourth embodiment of the invention.

FIG. 11 is side view of major part of the sample-setting portion according to the fifth embodiment of the invention.

### DETAILED DESCRIPTION OF THE INVENTION

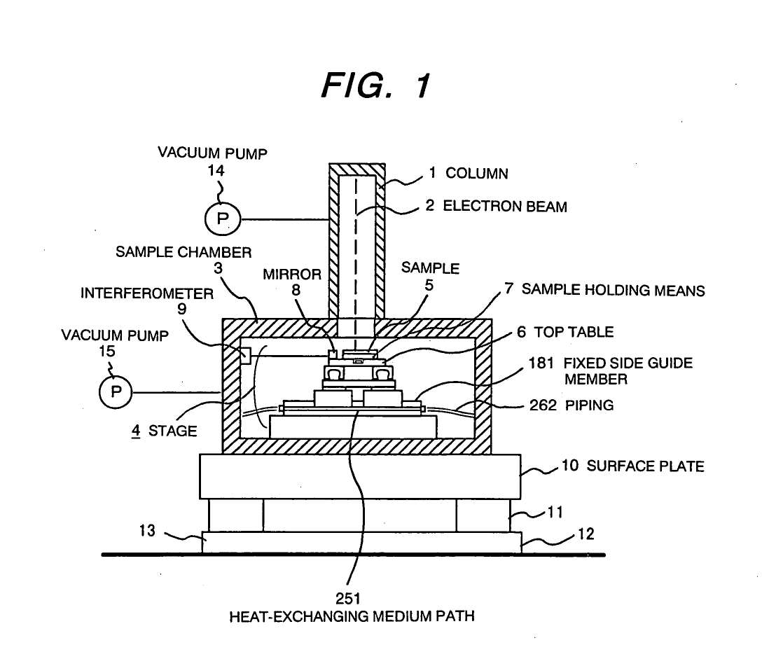

Embodiments of the present invention are described hereunder, using FIG. 1 to FIG. 11.

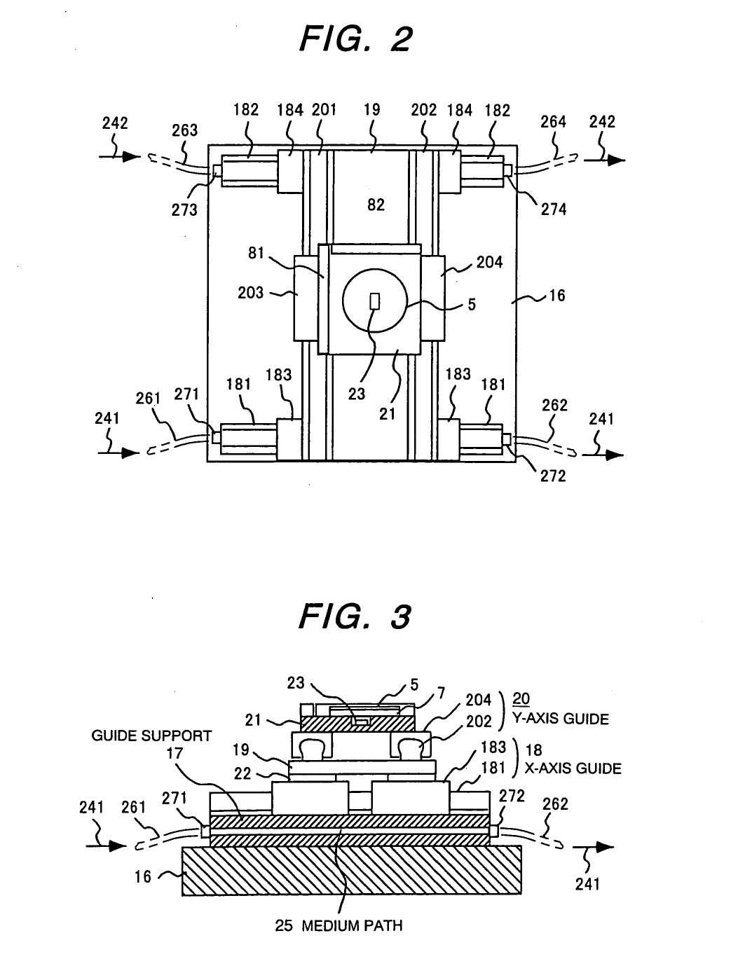

FIG. 1 is a brief construction diagram of an electron-beam drawing apparatus that employs the sample-setting moving stage according to an embodiment of the invention. In FIG. 1, the electron beam 2 generated in a column 1 is radiated onto a sample 5 placed on the stage 4 in the sample chamber 3. The top table 6, a component part of the stage 4, is equipped with a sample holding means (sample holding mechanism) 7 and mirror 8, and the sample position is detected and controlled by measuring with laser the distance via the mirror 8. An interferometer 9 is installed in the vacuum so that the laser is not easily affected by the fluctuation of the air and change in the atmospheric pressure. The sample chamber 3 is mounted on a surface plate 10 and the surface plate 10 is supported by a mount 11 with a vibration isolation function. Besides, the mount 11 is placed on a base 13 installed on the floor 12. The column 1 and sample chamber 3 is evacuated by the vacuum pumps 14 and 15 so that the high degree of vacuum is maintained in the electron beam path. In this embodiment, of the guide that guide the movement of the top table 6, a flow path 251 of the heat-exchanging medium, incoming through a pipe 262, is provided inside the non-moving fixed side guide member 181. More detailed description is given hereunder, using FIG. 2 and so on.

FIG. 2 is a plan view of the stage 4 shown in FIG. 1. FIG. 3 is a side view of the stage according to the first embodiment of the invention, and important components are specially shown with cross section. The stage 4 is installed on the stage base 16, which is the floor of the sample chamber 3. The X-axis (the first) guide 18 is mounted on the guide support 17 on the stage base 16, and the X-axis moving table 19 is set on the guide 18. The Y-axis (the second) guide 20 is mounted on the X-axis moving table 19, and then the sample-setting table (top table) 21, movable in both X-axis and Y-axis directions, is mounted on them. The sample holding mechanism 7 and mirrors 81 and 82 are installed on the top table 21, and a sample 5 is set on the sample holding mechanism 7.

To be concrete, the fixed side guide members 181 and 182 of the X-axis guide 18 are located in two rows on the guide support 17 mounted on the stage base 16, and the moving side guide members 183 and 184 moves in the X-axis direction along them. The moving table 19 is mounted on the guide members 183 and 184, using an elastic body 22 as cushion. The fixed side guide members 201 and 202 of the Y-axis guide 20 are mounted in two rows on the moving table 19. The moving side guide members 203 and 204 of the Y-axis guide 20 are so mounted as to be able to move in the Y-axis direction along the two rows of the fixed side guide members 201 and 202, respectively. The top table 21 mounted on the moving side guide members 203 and 204 can move in two dimensions along the X-axis and Y-axis directions.

Thus, the sample position can be detected and controlled by measuring with laser the distance via the mirrors 81 and 82.

A temperature sensor 23 is mounted on the top table 21, which can measure the temperature near the sample 5 or that on the top table 21.

As known from FIGS. 2 and 3, the flow path 25 of the heat-exchanging medium 241 and 242 is formed inside the guide support 17, to which pipes 261 to 264 are connected with joints 271 to 274, respectively. The arrow mark in the figure shows the direction of flow of the coolant 241 and 242.

Explanation of the temperature adjustment is given hereunder. The temperature of the medium 24 is controlled by a temperature adjustment means (device), not shown, based on the information from the temperature sensor 23 on the top table 21 so as to adjust the temperature of the sample-setting portion accordingly via the guide support 17. The heat change resulting from the temperature adjustment is transferred in the following sequence, and can be detected by the temperature sensor 23 installed near the sample 5. That is, the heat transfers in sequence from the X-axis fixed side guide members 181 and 182 to the X-axis moving side guide members 183 and 184, elastic body 22, moving table 19, Y-axis fixed side guide members 201 and 202, Y-axis moving side guide members 203 and 204, and to the top table 21.

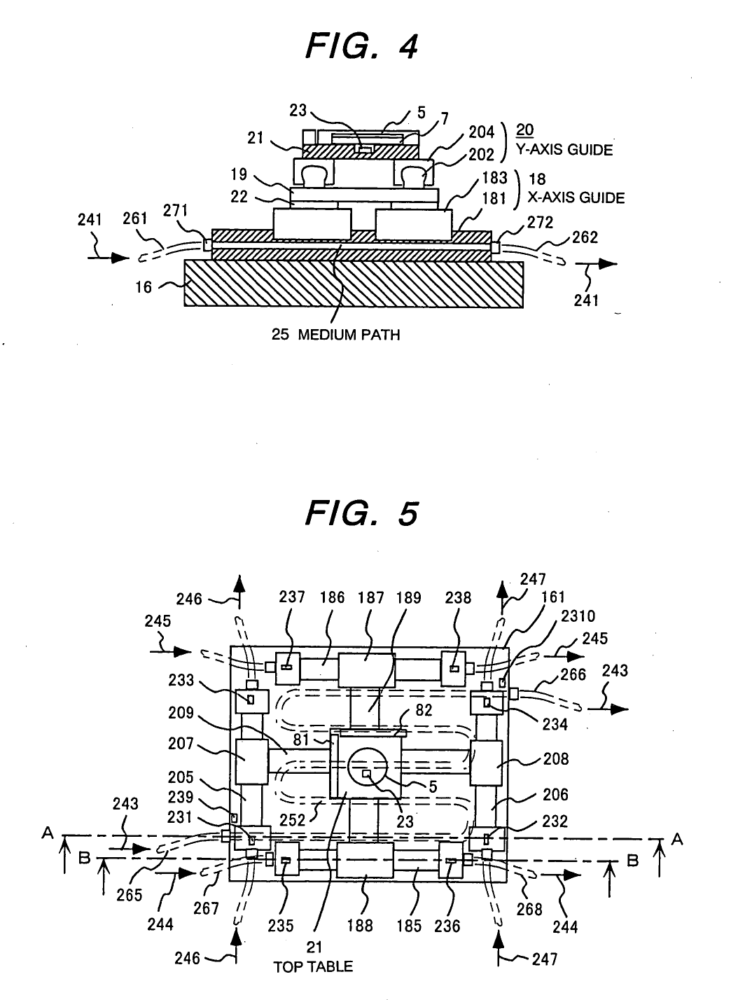

FIG. 4 is a modification to FIG. 3 according to the second embodiment of the invention. It differs from FIG. 3 in a point that no guide support 17 is installed and that the flow path 25 of the heat-exchanging medium is formed inside the X-axis fixed side guide members 181 and 182. Others are completely the same as shown in FIG. 3.

As shown in the figure, the flow path 25 of the heat-exchanging medium is formed inside the non-moving fixed side guide members 181 and 182 of the first (X-axis) guide 18 or inside the guide support member 17 attached closely to the fixed side guide members 181 and 182. Since the moving side guide members 183 and 184 of the first (X-axis) guide 18 and the members 201 to 204 of the second (Y-axis) guide 20 are supposed to move, no flow path of the heat-exchanging medium is formed inside any of them. Because of the above, the pipes 261 to 264 can be installed as stationary structure, and hence the effects below can be produced.

(1) There is no concern about dust generation due to friction and fatigue due to repeated movement involved in movable installation of the pipes 261 to 264 for the coolant flow 241 and 242.

(2) Temperature control can be applied to a position closest, in terms of both distance and heat transfer, to the sample 5 and sample holding mechanism 7 (sample-setting portion) than any other stationary portion, and hence the efficiency of the temperature adjustment is very high.

With the above embodiment, the temperature adjustment of the sample-setting portion can be performed efficiently while preventing the risk of dust generation and pipe breakage.

On the other hand, since the time constant of the heat transfer in the above embodiment is considerable, the flow rate or temperature change rate of the heat-exchanging medium must be higher if the temperature of the top table needs to be changed quickly. Since a temperature change is caused also in the stage base 16 and moving table 19 accordingly, there arises a fear that, if the coefficient of thermal expansion of the fixed side guides, mounted onto these components, is greatly different from that of the components, two sides may exhibit different elongation and the components may deform. To prevent the deformation of the moving table 19, an elastic body 22, easy to transform in the horizontal direction, is put between the moving table 19 and moving guide members 183 and 184 of the first guide 18. A similar effect can be expected if an elastic body is also put between the stage base 16 and guide support 17 (FIG. 3) or between the stage base 16 and fixed side guide members 181 and 182 of the first guide 18 (FIG. 4), although not shown. Besides, increasing the contact area of each component or constructing each component from material with higher heat transfer ratio is effective to lessen the time constant.

Although the guide in this embodiment is based on rolling lubrication of rolling element, a similar effect can be produced in the case of contact-sliding type guide.

FIG. 5 to FIG. 11 show an air bearing stage under vacuum, using a gas-lubrication type guide, according to other embodiments of the invention.

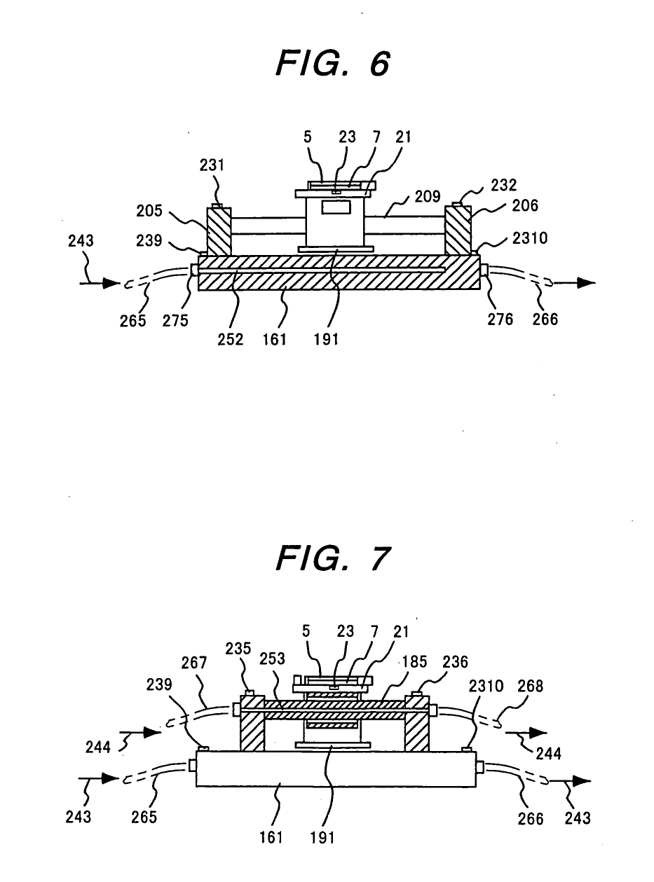

FIG. 5 is a plan view of the stage 4 in FIG. 1 according to the third embodiment of the invention. FIG. 6 shows the A-A cross-section and FIG. 7 shows the B-B cross section of the stage.

The fixed side guide members 185 and 186 of the X-axis first guide 18 are mounted on the stage base 161. The moving guide members 187 and 188 are connected to the top table 21 with a guide bar 189. The fixed side guide members 205 and 206 of the Y-axis second guide 20 are mounted in a similar manner. The moving guide members 207 and 208 are connected to the top table 21 with a guide bar 209. The movement of the moving table 191 in the X-axis and Y-axis direction is controlled by each guide bar 189 and 209, and the upward and downward movement is controlled by air lubrication with the stage base 161. In other words, the moving table 191 and stage base 161 constitute the moving side guide member and fixed side guide member of the air-lubrication type third guide. The top table 21 for setting the sample 5 and mirrors 81 and 82 is mounted on the moving table 191, and the temperature sensor 23 is mounted on the top table 21.

As known from FIG. 5 and FIG. 6, the flow path 252 of the heat-exchanging medium 243 is widely extended inside the stage base (constituting the fixed side guide member) 161. Since the flow path 252 covers almost whole area of the plane of the top table 21 movement, the flow path 252 of the heat-exchanging medium 243 is located just under the sample-setting portion irrespective of its position, and hence the temperature control is performed effectively.

As known from FIG. 5 and FIG. 7, the flow paths 253 and 254 of the heat-exchanging medium 244 and 245 are formed inside the fixed side guide members 185 and 186 of the first (X-axis) guide 18. The flow paths of the heat-exchanging medium 246 and 247 are formed, not shown, inside the fixed side guide members 205 and 206 of the second (Y-axis) guide 20 in a similar manner. On the other hand, a number of temperature sensors 23, comprising 231 to 2310, are installed in the heat transfer path from the stage base 161 to the sample-setting portion for measuring the temperature of each portion. The temperature of the heat-exchanging medium 243 to 247 can be controlled independently from each other, and so constant temperature control over the sample-setting portion and preventive control over the distortion due to the difference of the coefficient of thermal expansion between the members are performed accordingly.

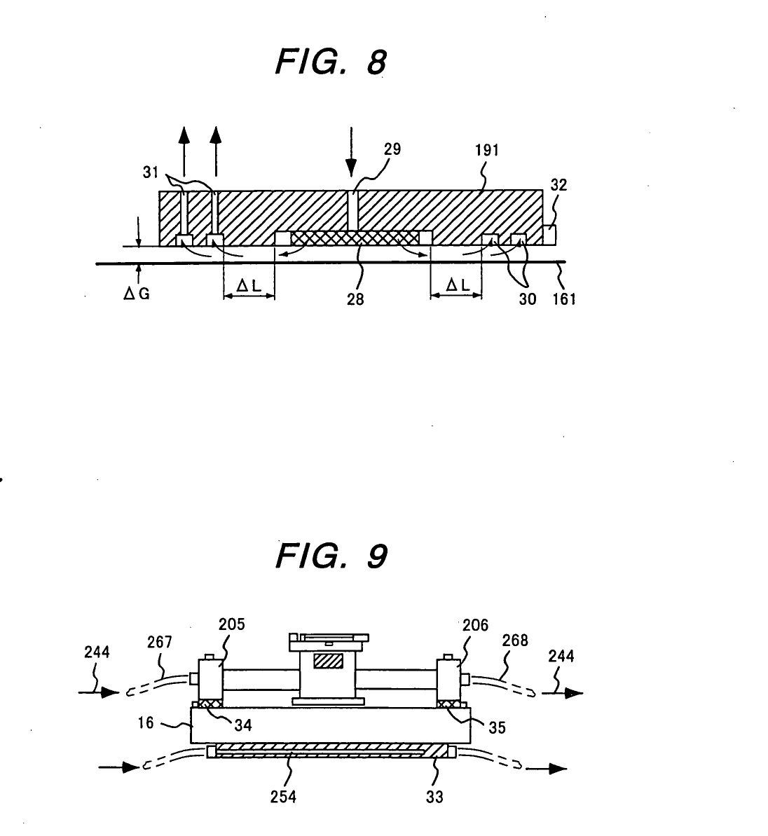

FIG. 8 shows typical gas lubrication under vacuum, used in the above embodiments of the invention. The gas outgoing from a porous bearing 28 flows through the gas exhaust groove 28, installed as if surrounding the porous bearing, and then exhausted by a vacuum pump, not shown, so as to maintain the degree of vacuum in the sample chamber. Generally, in the case of gas-lubrication type guide, the clearance ΔG between the fixed side guide member (stage base) 161 and moving side guide member (moving table) 191 is as small as several to tens [μm]. Because of this, the heat is exchanged between the fixed side guide member 161 and moving side guide member 191 via the fluid flowing in the clearance, and the heat of the fixed side guide member 161 is transferred to the moving side guide member 191. Besides, if the distance ΔL from the porous bearing 28 to the gas exhaust groove 28 is longer, thermal contact area becomes wider and so the heat exchange between the fixed side guide member 161 and moving side guide member 191 becomes easier. 31 denotes an exhaust pipe and 32 denotes a gap sensor.

In this embodiment, for the moving table 191, heat is exchanged between the guide bars 189 and 209, which are thermally connected to the fixed side guide member 161 opposite to the moving table, and stage base 161, and so the top table 21 can be set to a desired temperature. If the coefficient of thermal expansion is different between the fixed side guide member 161 and stage base 161, and if a similar temperature change is caused, the fixed side guide member 161 and stage base 161 deforms because the quantity of thermal expansion or contraction is different, resulting in deteriorated position accuracy. In addition, if the deformation is great enough to exceed the clearance between the fixed side guide member 161 and moving side guide member 191, scuffing is caused between the guide members and so the gas lubrication itself may not remain functional. To prevent the above problem, as afore-mentioned, a number of temperature sensors 23 are installed on the fixed side guide member 161 and moving side guide member 191 so as to control the temperature or flow rate of the heat-exchanging medium independently, taking into account the coefficient of thermal expansion of each component. Besides, as shown in FIG. 8, the above can also be prevented where a gap sensor 32 capable of detecting minute displacement is installed on the moving side guide member 191 to measure the gap ΔG to the fixed side guide member 161 and the temperature of each guide is controlled so that the gap variation due to the temperature change becomes less. For example, for the temperature of the top table 21, the temperature of the stage base 161 is mainly adjusted and the temperature of the fixed side guide member 161 is also controlled based on the information from the gap sensor 32. With this control, the top table 21 can be set to a desired temperature while preventing the deformation of each component.

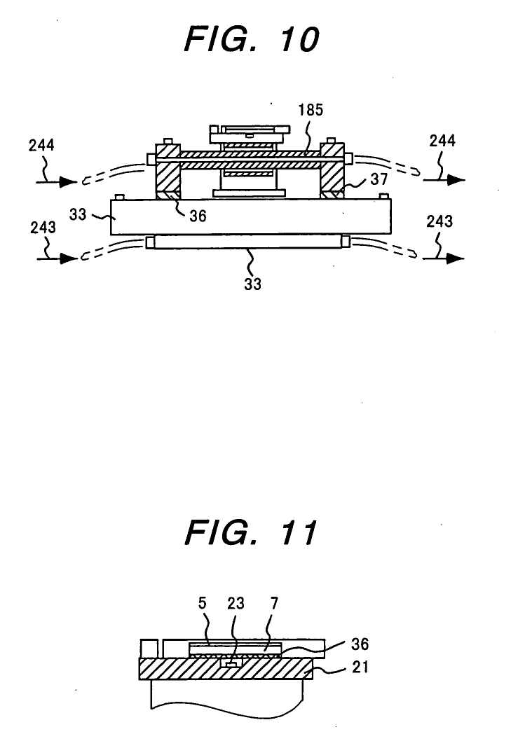

FIG. 9 and FIG. 10 are each side view of the stage 4, partly shown in cross section, according to the fourth embodiment of the invention. In this embodiment, instead of providing a flow path of the heat-exchanging medium inside the stage base 16, a temperature control member 33 is attached closely to the stage base 16 and the temperature control of the stage base 16 is performed indirectly. A flow path 254 of the heat-exchanging medium 248 is provided inside the temperature control member 33.

With this construction, simply by attaching the temperature control plate (member) 33 to the stage base 16, it is no longer necessary to form a complicated flow path inside the stage base 16. Since the rigidity of the stage base 16 can be maintained high because of the above, the guide surface can be finished with high accuracy. In addition, elastic bodies 34 and 35, easy to transform in the horizontal direction, are put between the fixed side guide members of the first and the second guides, for example 205 and 206, and the stage base 16. By using the elastic bodies 34 and 35 as cushion, it becomes relatively easy to prevent the deformation of the fixed side guide members, for example 205 and 206, and stage base 16 resulting from the difference in the coefficient of thermal expansion of each component or sharp temperature gradient.

FIG. 11 is a side view of major part of the sample-setting portion according to the fifth embodiment of the invention. As shown in the figure, where an electric heat generation or absorption means (for example, Peltier element or heater) 36, which can control the temperature electrically, is used on the top table 21, temperature control capable of corresponding to a temperature change in a short time becomes available. If a heater capable of heating only is employed, the temperature of the heat-exchanging medium is controlled so that the top table 21 is always set lower than a desired temperature without using the heater. Thus, while the temperature controller controls only the heating ON/OFF of the heater 36 based on the information from the temperature sensor 23, the top table 21 can be controlled at a desired temperature.

When the stage 4 as explained above is applied to a semiconductor manufacturing apparatus or inspection apparatus, typically to an electron-beam drawing apparatus, it becomes possible to control the temperature of the sample-setting portion and perform exposure and inspection of the sample accurately while preventing the risk of dust generation, damage to the vacuum pump and contamination in a vacuum atmosphere.

According to the present invention, it is possible to realize the temperature control of the sample-setting portion and perform exposure or inspection of samples accurately while preventing the generation of dust, deterioration of the degree of vacuum and contamination in a vacuum atmosphere.

What is claimed is

1. A sample-setting moving stage, comprising
a table on which a sample is set under vacuum or reduced pressure atmosphere,
a guide, consisting of a moving side and a fixed side, that guides the movement of the table by means of the relative movement of the two sides,
a temperature sensor installed near the sample-setting portion,
a flow path of the heat-exchanging medium that cools the sample-setting portion via the guide, and
a temperature adjustment means that adjusts the temperature of the sample-setting portion by means of the heat-exchanging control;
the flow path of the heat-exchanging medium being provided through the inside of the non-moving fixed side guide member of the two constituent members of the guide.

2. A sample-setting moving stage, comprising
a table on which a sample is set under vacuum or reduced pressure atmosphere,
a guide, consisting of a moving side and a fixed side, that guides the movement of the table by means of the relative movement of the two sides,
a temperature sensor installed near the sample-setting portion,
a flow path of the heat-exchanging medium that cools the sample-setting portion via the guide, and
a temperature adjustment means that adjusts the temperature of the sample-setting portion by means of the heat-exchanging control;
the flow path of the heat-exchanging medium being provided through the inside of a member attached closely to the non-moving fixed side guide member.

3. A sample-setting moving stage according to claim 1, wherein the guide is equipped with a means for sliding the moving side guide member and fixed side guide member with the aid of gas lubrication.

4. A sample-setting moving stage, comprising
a table on which a sample is set under vacuum or reduced pressure atmosphere,
the first guide and the second guide that guide the movement of the table in the X-axis direction and Y-axis direction in a plane, respectively,
a temperature sensor installed near the sample-setting portion,
a flow path of the heat-exchanging medium that cools the sample-setting portion via the guide, and
a temperature adjustment means that adjusts the temperature of the sample-setting portion by means of the heat-exchanging control; and
further comprising a gas-lubrication type third guide that guides the table in every direction in the plane;
the flow path of the heat-exchanging medium being provided through the inside of the non-moving fixed side guide member of the two constituent members of the third guide or through the inside of a member attached to the fixed side guide member.

5. A sample-setting moving stage according to claim 4, wherein the flow path of the heat-exchanging medium is so widely extended that the flow path is located just under the table almost everywhere in the plane of the table movement.

6. A sample-setting moving stage according to claim 1, further comprising
the second temperature sensor, installed in the heat transfer path from the flow path of the heat-exchanging medium to the sample-setting table, and
multiple lines of flow path of the heat-exchanging medium; wherein
the temperature adjustment means adjusts the temperature of the medium, flowing in the multiple lines of flow path independently from each other, based on the information from the second temperature sensor and from the temperature sensor installed near the sample.

7. A sample-setting moving stage according to claim 1, wherein
an electric heat generation or absorption means is installed near the sample, and
the temperature adjustment means adjusts the electric heat generation or absorption means based on the information from the temperature sensor.

8. A sample-setting moving stage according to claim 1, further comprising
an electric heat generation means installed near the sample, and
a temperature controller that controls, based on the information from the temperature sensor, so that the temperature of the sample-setting portion be closer to desired; wherein
the temperature adjustment means adjusts the temperature of the sample-setting portion, using the heat-exchanging medium while the electric heat generation means is not in operation, so that the temperature of the sample-setting portion be lower than desired.

9. A manufacturing apparatus for circuit pattern, on which a circuit pattern is formed on a sample by irradiation of charged particle ray, X-ray or extreme ultraviolet (EUV), equipped with a sample-setting moving stage according to claim 1.

10. An inspection apparatus for circuit pattern, on which charged particle ray is radiated onto a sample with circuit pattern so as to inspect the circuit pattern, equipped with a sample-setting moving stage according to claim 1.
